(19) United States
(12) Patent Application Publication
(10) Pub. No.: US 2025/0107096 A1
(43) Pub. Date: Mar. 27, 2025

(54) MEMORY DEVICE INCLUDING TWO-DIMENSIONAL MATERIAL

(71) Applicant: Samsung Electronics Co., Ltd., Suwon-si (KR)

(72) Inventors: Yeonchoo CHO, Suwon-si (KR); Junyoung KWON, Suwon-si (KR); Huije RYU, Suwon-si (KR); Minsu SEOL, Suwon-si (KR)

(73) Assignee: Samsung Electronics Co., Ltd., Suwon-si (KR)

(21) Appl. No.: 18/581,186

(22) Filed: Feb. 19, 2024

(30) Foreign Application Priority Data
Sep. 27, 2023 (KR) 10-2023-0131171

(51) Int. Cl. H10B 43/30; H10B 43/27

(52) U.S. Cl. CPC H10B 43/30; H10B 43/27

(57) ABSTRACT

A memory device may include a gate electrode, a channel layer spaced apart from the gate electrode, a charge trap layer between the gate electrode and the channel layer, and a two-dimensional material layer arranged between the charge trap layer and the gate electrode. The two-dimensional material layer may include a material having an electron affinity of less than 1 eV.

### CROSS-REFERENCE TO RELATED APPLICATION

This application is based on and claims priority under 35 U.S.C. § 119 to Korean Patent Application No. 10-2023-0131171, filed on Sep. 27, 2023, in the Korean Intellectual Property Office, the disclosure of which is incorporated by reference herein in its entirety.

### BACKGROUND

### 1. Field

The disclosure relates to a memory device including a two-dimensional material.

### 2. Description of the Related Art

As conventional hard disks are replaced by solid state drives (SSDs), NAND flash memory devices, which are nonvolatile memory devices, are becoming widely commercialized. Recently, due to miniaturization and high integration, vertical memory devices in which multiple memory cells are stacked in a direction perpendicular to a substrate have been developed. Vertical NAND flash memory devices perform memory functions by adjusting a threshold voltage of a transistor by adjusting charges in a charge trap layer. The range of the threshold voltage is proportional to the range of a charge density of charges in the charge trap layer. The range of the threshold voltage may not be expanded due to a narrow range of the charge density of charges in the charge trap layer.

### SUMMARY

Provided are memory devices with improved trap density of a charge trap layer and reduced side charge diffusion of the charge trap layer.

Additional aspects will be set forth in part in the description which follows and, in part, will be apparent from the description, or may be learned by practice of the presented embodiments of the disclosure.

According to an embodiment, a memory device may include a gate electrode, a channel layer spaced apart from the gate electrode, a charge trap layer between the gate electrode and the channel layer, and a two-dimensional material layer between the charge trap layer and the gate electrode. The two-dimensional material layer may include a material having an electron affinity of less than 1 eV.

In some embodiments, the two-dimensional material layer may include at least one of CaF₂, NaF, MgF₂, CdF₂, MoS₂, MoSe₂, WS₂, and WSe₂.

In some embodiments, the two-dimensional material layer may include an insulator material.

In some embodiments, the two-dimensional material layer may include a material with a band gap of 10 eV or more.

In some embodiments, a sum of a thickness of the two-dimensional material layer and a thickness of the charge trap layer may be 10 nm or less.

In some embodiments, the two-dimensional material layer may include a first two-dimensional material layer and a second two-dimensional material layer.

In some embodiments, the first two-dimensional material layer and the second two-dimensional material layer may include different materials.

In some embodiments, the charge trap layer may include a material having a trap density of 10¹⁸/cm³ or more and 10²⁰/cm³ or less.

In some embodiments, the charge trap layer may include silicon nitride, SiO₂, HfO₂, or TiO₂.

In some embodiments, the charge trap layer may include a plurality of grain boundaries.

In some embodiments, the memory device may further include a tunneling barrier layer between the charge trap layer and the channel layer.

In some embodiments, the memory device may further include a blocking insulating layer between the two-dimensional material layer and the gate electrode.

According to an embodiment, a memory device may include a substrate and a plurality of memory cell arrays on the substrate. Each of the plurality of memory cell arrays may include a channel layer extending in a first direction, a plurality of gate electrodes spaced apart from the channel layer in a second direction and spaced apart from each other in the first direction, a charge trap layer between the channel layer and the gate electrode, and a two-dimensional material layer between the charge trap layer and the plurality of gate electrodes. The second direction may be different than first direction. The two-dimensional material layer may include a material having electron affinity of less than 1 eV.

In some embodiments, the two-dimensional material layer may include at least one of CaF₂, NaF, MgF₂, CdF₂, MoS₂, MoSe₂, WS₂, and WSe₂.

In some embodiments, the two-dimensional material layer may include a material with a band gap of 10 eV or more.

The memory cell array may extend in a direction perpendicular to the substrate.

In some embodiments, the two-dimensional material layer may include a first two-dimensional material layer and a second two-dimensional material layer.

In some embodiments, the charge trap layer may include a material having a trap density of 10¹⁸/cm³ or more and 10²⁰/cm³ or less.

In some embodiments, the charge trap layer may include silicon nitride, SiO₂, HfO₂, or TiO₂.

In some embodiments, the charge trap layer may include a plurality of grain boundaries.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view schematically illustrating a memory device according to an embodiment;

FIG. 2 is a cross-sectional view schematically illustrating a memory device according to another embodiment;

FIG. 3 is a cross-sectional view illustrating a schematic structure of a memory device according to an embodiment;

FIG. 4 is a perspective view illustrating a schematic structure of a memory cell array included in the memory device of FIG. 3;

FIGS. 5A to 5E are diagrams illustrating a method of manufacturing the memory cell array of FIG. 4; and

FIG. 6 is a conceptual diagram schematically showing a device architecture applicable to an electronic device according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, a memory device including a two-dimensional material according to various embodiments will be described in detail with reference to the accompanying drawings. In the following drawings, the same reference numerals refer to the same components, and the size of each component in the drawings may be exaggerated for clarity and convenience of description. In addition, embodiments described below are merely illustrative, and various modifications are possible from these embodiments.

Hereinafter, the term “upper portion” or “on” may also include “to be present above on a non-contact basis” as well as “to be on the top portion in directly contact with”. The singular expression includes plural expressions unless the context clearly implies otherwise. In addition, when a part “includes” a component, this means that it may further include other components, not excluding other components unless otherwise descried.

The use of the term “the” and similar indicative terms may correspond to both singular and plural. Unless there is clear order or contrary description of the steps constituting the method, these steps may be performed in the appropriate order, and are not necessarily limited to the order described.

The connection or connection members of lines between the components shown in the drawings exemplarily represent functional connection and/or physical or circuit connections, and may be replaceable or represented as various additional functional connections, physical connections, or circuit connections in an actual device.

The use of all examples or illustrative terms is simply to describe technical ideas in detail, and the scope is not limited due to these examples or illustrative terms unless the scope is limited by the claims.

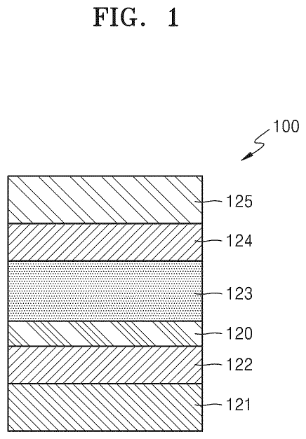

FIG. 1 is a cross-sectional view schematically illustrating a memory device according to an embodiment.

Referring to FIG. 1, a memory device 100 according to an embodiment may include a gate electrode 121, a channel layer 125 spaced apart from the gate electrode 121, a charge trap layer 123 arranged between the gate electrode 121 and the channel layer 125, and a two-dimensional material layer 120 arranged between the charge trap layer 123 and the gate electrode 121.

The gate electrode 121 controls the corresponding channel layer 125, and a word line may be electrically connected to the gate electrode 121. The gate electrode 121 may include, for example, a metal material having excellent electrical conductivity, such as gold (Au) or titanium (Ti), metal nitride, impurity-doped silicon, or a two-dimensional conductive material. However, this is only an example, and the gate electrode 121 may include various other materials.

The channel layer 125 may include a semiconductor material. The channel layer 125 may include, for example, Si, Ge, SiGe, group III-V semiconductor, or the like. In addition, the channel layer 125 may include, for example, oxide semiconductors, nitride semiconductors, oxynitride semiconductors, two-dimensional (2D) semiconductor materials, quantum dots, or organic semiconductors. Here, the oxide semiconductor may include, for example, InGaZnO or the like, the two-dimensional semiconductor material may include, for example, transition metal dichalcogenide (TMD) or graphene, and the quantum dot (QD) may include a colloidal QD, a nanocrystal structure, or the like. However, this is only an example, and the embodiments are not limited thereto.

The channel layer 125 may further include a dopant. The dopant may include a p-type dopant or an n-type dopant. The p-type dopant may include, for example, a Group III element such as B, Al, Ga, In, or the like, and the n-type dopant may include, for example, a Group V element such as P, As, Sb, or the like.

The two-dimensional material layer 120 includes a two-dimensional material having a two-dimensional crystal structure. The two-dimensional material layer 120 may include a material having an electron affinity of less than 1 eV. The two-dimensional material layer 120 may limit and/or prevent electrons moving from the channel layer 125 to the charge trap layer 123 from reaching the gate electrode 121 by including a material having an electron affinity of less than 1 eV.

The two-dimensional material layer 120 may include at least one of CaF₂, NaF, MgF₂, CdF₂, MoS₂, MoSe₂, WS₂, and WSe₂. However, the two-dimensional material layer 120 is not limited thereto. In addition, the two-dimensional material layer 120 may include the aforementioned materials as they are, but may be doped to further improve the electrical properties of the memory device 100. In other words, some of the elements constituting the two-dimensional crystal structure of the two-dimensional material layer 120 may be replaced with other elements or the two-dimensional material layer 120 may have a doped structure by additionally combining other elements with the two-dimensional crystal structure.

The two-dimensional material layer 120 may include an insulator. The two-dimensional material layer 120 may include a material having a large band gap. The two-dimensional material layer 120 may include, for example, a material having a band gap of 5 eV or more. The two-dimensional material layer may include, for example, a material having a band gap of 10 eV or more.

The charge trap layer 123 may store introduced charges. Charges (e.g., electrons) present in the channel layer 125 may enter the charge trap layer 123 by a tunneling effect or the like. Charges introduced into the charge trap layer 123 may be fixed to the charge trap layer 123.

The charge trap layer 123 may include a material having a high trap density. The charge trap layer 123 may include a material having a trap density of about 10¹⁸/cm³ or more and about 10²⁰/cm³ or less. The charge trap layer 123 may include silicon nitride. Silicon constituting the charge trap layer 123 may be uniformly distributed inside the charge trap layer 123 or may be distributed in a layer-by-layer (LBL) structure. The charge trap layer 123 may include SiO₂, HfO₂, or TiO₂.

A sum of thicknesses of the two-dimensional material layer 120 and the charge trap layer 123 may be, for example, about 10 nm or less. A sum of thicknesses of the two-dimensional material layer 120 and the charge trap layer 123 may be, for example, about 5 nm or less.

The two-dimensional material layer 120 has low surface energy due to a feature that does not form a covalent bond in a vertical direction. When a three-dimensional charge trap layer 123 is formed on the two-dimensional material layer 120, the charge trap layer 123 develops island growth. Therefore, the charge trap layer 123 includes a plurality of grain boundaries. The plurality of grain boundaries may serve to limit and/or prevent lateral charge spreading inside the charge trap layer 123. Accordingly, the reliability of the memory device 100 may be improved.

In the memory device 100 according to an embodiment, the charge trap layer 123 may be provided on the two-dimensional material layer 120 to increase trap density compared to a charge trap layer without a conventional two-dimensional material layer 120. The trap density means the number of trapped charges per unit volume. As the trap density increases, the threshold voltage control range of the memory device 100 increases, and the memory window of the memory device 100 expands to implement a high-efficiency memory device 100.

The memory device 100 may further include a tunneling barrier layer 124 arranged between the charge trap layer 123 and the channel layer 125. The tunneling barrier layer 124 is a layer in which charges are tunneled. The tunneling barrier layer 124 may include, for example, silicon oxide or metal oxide.

The memory device 100 may further include a blocking insulating layer 122 arranged between the two-dimensional material layer 120 and the gate electrode 121. The blocking insulating layer 122 may function as a barrier for limiting and/or preventing a charge transfer between the charge trap layer 123 and the gate electrode 121. The blocking insulating layer 122 may include, for example, silicon oxide or metal oxide.

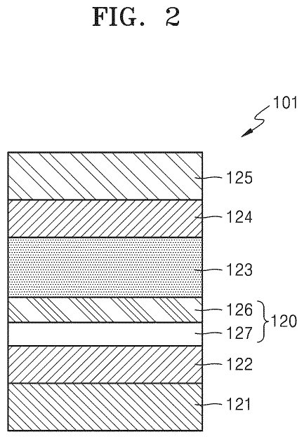

FIG. 2 is a cross-sectional view schematically illustrating a memory device according to another embodiment.

Referring to FIG. 2, a memory device 101 according to another embodiment may include a gate electrode 121, a channel layer 125 spaced apart from the gate electrode 121, a charge trap layer 123 arranged between the gate electrode 121 and the channel layer 125, and a two-dimensional material layer 120 arranged between the charge trap layer 123 and the gate electrode 121. The gate electrode 121, the channel layer 125, and the charge trap layer 123 may be the same as the gate electrode 121, the channel layer 125, and the charge trap layer 123 of FIG. 1. In describing FIG. 2, redundant descriptions of FIG. 1 are omitted.

The two-dimensional material layer 120 may be formed in a layered structure. The two-dimensional material layer 120 may include a first two-dimensional material layer 126 and a second two-dimensional material layer 127. However, the embodiments are not limited thereto, and the two-dimensional material layer 120 may be configured to have a plurality of two-dimensional material layers. The layers of the two-dimensional material layer 120 may interact through van der Waals force. Since the two-dimensional material layer 120 may be formed in units of layers, the thickness of the two-dimensional material layer 120 may be easily adjusted.

The first two-dimensional material layer 126 and the second two-dimensional material layer 127 are formed of a two-dimensional material having a two-dimensional crystal structure. The first two-dimensional material layer 126 and the second two-dimensional material layer 127 may include a material having an electron affinity lower than 1 eV. The first two-dimensional material layer 126 and the second two-dimensional material layer 127 may include a material having an electron affinity lower than 1 eV, and may limit and/or prevent electrons moving from the channel layer 125 to the charge trap layer 123 from reaching the gate electrode 121.

The first two-dimensional material layer 126 and the second two-dimensional material layer 127 may include at least one of CaF₂, NaF, MgF₂, CdF₂, MoS₂, MoSe₂, WS₂, and WSe₂. The first two-dimensional material layer 126 and the second two-dimensional material layer 127 may include different materials.

A sum of thicknesses of the charge trap layer 123, the first two-dimensional material layer 126, and the second two-dimensional material layer 127 may be, for example, about 10 nm or less. The sum of the thicknesses of the charge trap layer 123, the first two-dimensional material layer 126, and the second two-dimensional material layer 127 may be, for example, about 5 nm or less.

The memory device 101 may further include a tunneling barrier layer 124 arranged between the charge trap layer 123 and the channel layer 125, and a blocking insulating layer 122 arranged between the two-dimensional material layer 120 and the gate electrode 121. The tunneling barrier layer 124 and the blocking insulating layer 122 of FIG. 2 may be the same as the tunneling barrier layer 124 and the blocking insulating layer 122 of FIG. 1.

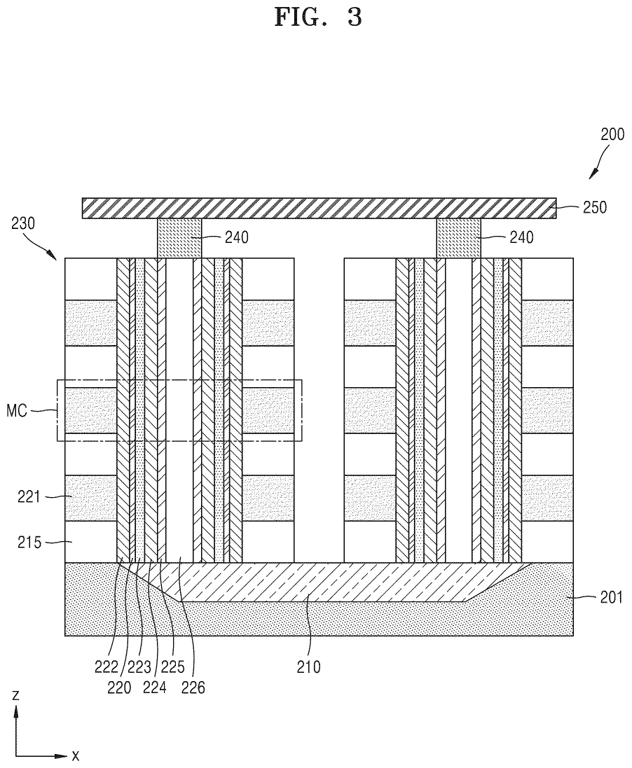

FIG. 3 is a cross-sectional view illustrating a schematic structure of a memory device according to an embodiment.

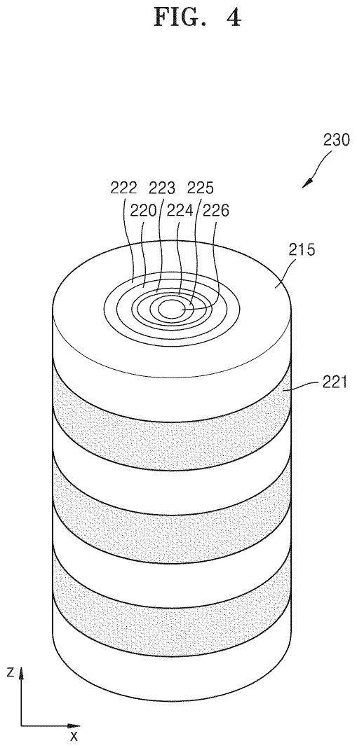

FIG. 4 is a perspective view illustrating a schematic structure of a memory cell array included in the memory device of FIG. 3.

The memory device of the present embodiment may be a flash NAND device based on a charge trap.

Referring to FIG. 3, a memory device 200 may include a substrate 201 and a plurality of memory cell arrays 230 provided on the substrate 201.

A channel layer 225, a desired and/or alternatively predetermined gate electrode 221 spaced apart from the channel layer 225, a blocking insulating layer 222 arranged corresponding to the gate electrode 221, a charge trap layer 223 arranged between the channel layer 225 and the gate electrode 221, a two-dimensional material layer 220 arranged between the charge trap layer 223 and the gate electrode 221, a tunneling barrier layer 224, and a filling insulating layer 226 form one memory cell MC, and a memory cell array 230 includes a plurality of memory cells MC arranged in one direction.

The gate electrode 221, the blocking insulation layer 222, the two-dimensional material layer 220, the charge trap layer 223, the tunneling barrier layer 224, and the channel layer 225 may be substantially the same as the gate electrode 121, the blocking insulation layer 122, the two-dimensional material layer 120, the charge trap layer 123, the tunneling barrier layer 124, and the channel layer 125 described with reference to FIGS. 1 and 2, respectively.

The memory device 200 may also include a common source region 210, in which the plurality of memory cell arrays 230 are arranged, a drain 240 provided on the memory cell array 230, and a bit line 250 provided on the drain 240.

Each of the memory cell arrays 230 may extend in a direction perpendicular to the substrate 201 (z-axis direction in FIG. 3). The plurality of memory cell arrays 230 may be arranged on the substrate 201 in various forms. The memory cell array 230 may have a cylindrical shape, but is not limited thereto, and may have, for example, a square column shape. Two memory cell arrays 230 are illustrated in the drawing, but this is an example, and the number of memory cells MC included in the memory cell array 230 is also an example.

The substrate 201 may include various materials. For example, the substrate 201 may include a single crystal silicon substrate, a compound semiconductor substrate, or a silicon on insulator (SOI) substrate, but is not limited thereto. In addition, the substrate 201 may further include impurity areas by doping, electronic devices such as transistors, or peripheral circuits that select and control memory cells that store data.

An interlayer insulating layer 215 and a gate electrode 221 may be alternately stacked on the substrate 201 in a direction perpendicular to the substrate 201. Each interlayer insulating layer 215 and each gate electrode 221 may be provided in parallel to the substrate 201.

The substrate 201 may include a silicon material doped with first type impurities. The substrate 201 may include, for example, a silicon material doped with p-type impurities. The substrate 201 may be, for example, a p-type well. However, the substrate 201 is not limited to p-type silicon.

The common source region 210 may be provided on the substrate 201. The common source region 210 may have a second type different from that of the substrate 201. The common source region 210 may have, for example, an n-type. However, the common source region 210 is not limited to an n-type.

The drain 240 may be provided on the memory cell array 230. The drain 240 may include, for example, a silicon material doped with a second type. For example, the drain 240 may include a silicon material doped with an n-type.

The bit line 250 may be provided on the drain 240. The drain 240 and the bit line 250 may be connected through contact plugs.

The memory cell array 230 may include the channel layer 225 extending in the first direction (e.g., the z-axis direction), a plurality of gate electrodes 221 spaced apart from the channel layer 225 in a second direction (e.g., the y-axis direction) different from the first direction and alternately arranged in the first direction perpendicular to the substrate 201, and the blocking insulating layer 222, the two-dimensional material layer 220, the charge trap layer 223, and the tunneling barrier layer 224 sequentially provided between the gate electrodes 221 and the channel layer 225 in a direction parallel to the substrate 201. Here, each of the blocking insulation layer 222, the two-dimensional material layer 220, the charge trap layer 223, the tunneling barrier layer 224, and the channel layer 225 is provided to extend in a direction perpendicular to the substrate 201 (e.g., the first direction) and may be shared by the plurality of memory cells MC.

The plurality of gate electrodes 221 are spaced apart from each other in the first direction. The number of illustrated gate electrodes 221 is an example and is not limited to the illustrated number. The number of the gate electrodes 221 corresponds to the number of the memory cells MC individually controlled by the memory device 200, and the corresponding memory cells MC may be controlled to be turned on/off according to the applied voltage. The gate electrode 221 may be connected to, for example, a word line, and a voltage for turning on or off the memory cell MC may be applied to the gate electrode 221 through the word line.

When a desired and/or alternatively predetermined voltage is applied to the gate electrode 221 corresponding to each memory cell MC, the charge flowing between the source and drain in the channel layer 225 corresponding to the gate electrode 221 passes through the tunneling barrier layer 224 and is captured in the charge trap layer 223 to thereby store information therein.

For example, when a memory cell MC is selected for recording, the area of the channel layer 225 corresponding to the selected memory cell MC is turned on, and a voltage that allows charge to be transferred from the channel layer 225 to the charge trap layer 222 through the tunneling barrier layer 224 is applied to the gate electrode 221. In the unselected memory cell MC, the area of the corresponding channel layer 225 is turned on, but a voltage of a degree in which charge does not move from the channel layer 225 to the charge trap layer 223 is applied to the gate electrode 221. In this way, a current flow is formed through the channel layer 225, and charge trap may be made only in the charge trap layer 223 corresponding to the selected memory cell MC. As such, information of 1 or 0 may be recorded according to the charge trap of the charge trap layer 223 in each memory cell MC.

The interlayer insulating layer 215 may serve as a spacer layer for insulation between the gate electrodes 221. The interlayer insulating layer 215 may include, for example, silicon oxide, silicon nitride, or the like, but is not limited thereto.

A channel hole is formed to penetrate in a direction perpendicular to the substrate 201 (z-axis direction) in the interlayer insulation layers 215 and the gate electrodes 221. The channel hole may be formed to have, for example, a circular cross section.

The blocking insulation layer 222, the two-dimensional material layer 220, the charge trap layer 223, the tunneling barrier layer 224, and the channel layer 225 are sequentially provided on the inner wall of the channel hole. Here, each of the blocking insulation layer 222, the charge trap layer 223, the tunneling barrier layer 224, and the channel layer 225 may be formed to have a cylindrical shape extending in a direction perpendicular to the substrate 201. The filling insulating layer 226 may be provided inside the channel layer 225 to fill the channel hole. The filling insulating layer 226 may include, for example, silicon oxide or air, but is not limited thereto.

The blocking insulating layer 222 may be provided on an inner wall of the channel hole to be in contact with the interlayer insulating layers 215 and the gate electrodes 221. The blocking insulating layer 222 may function as a barrier for limiting and/or preventing a charge transfer between the charge trap layer 223 and the gate electrode 221. The blocking insulating layer 222 may include, for example, silicon oxide or metal oxide, but is not limited thereto. The tunneling barrier layer 224 may be provided between the charge trap layer 223 and the channel layer 225. The tunneling barrier layer 224 is a layer in which charge tunneling is performed, and may include, for example, silicon oxide or metal oxide, but is not limited thereto.

The memory elements 100, 101, and 200 described above may be used for storing data in various electronic devices.

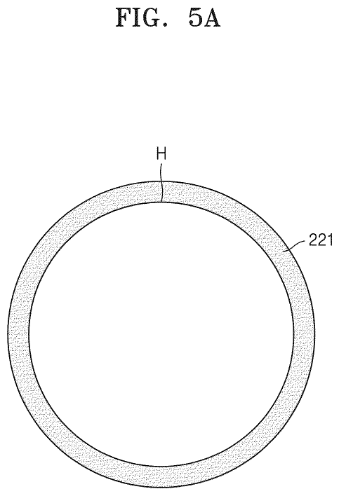

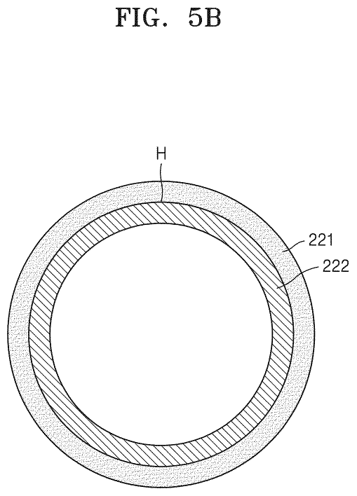

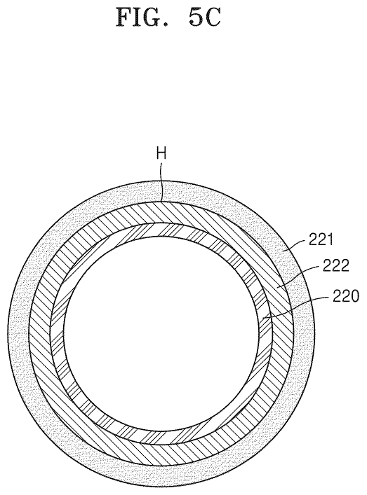

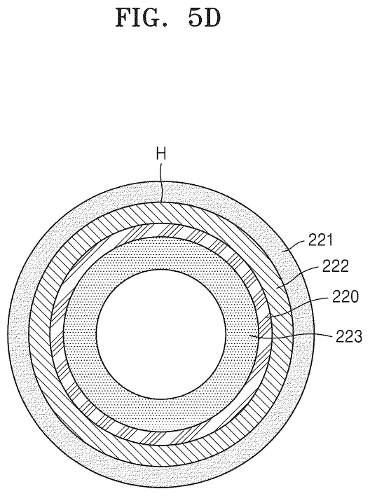

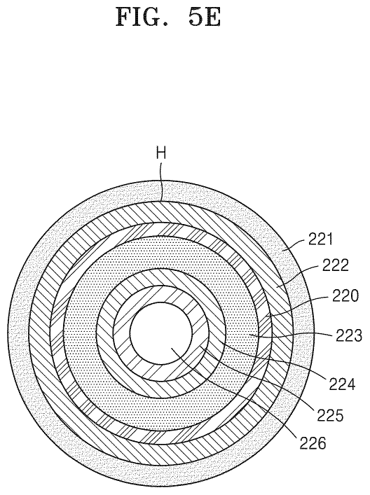

FIGS. 5A to 5E are diagrams illustrating a method of manufacturing the memory cell array of FIG. 4.

Referring to FIG. 5A, the channel hole H may be formed by etching the gate electrode 221. The channel hole H may be formed to have, for example, a circular cross section, but is not limited thereto.

Referring to FIG. 5B, the blocking insulating layer 222 may be formed on an inner wall of the channel hole H.

Referring to FIG. 5C, the two-dimensional material layer 220 may be formed to be in contact with the blocking insulating layer 222. The two-dimensional material layer 220 may be configured to have a plurality of two-dimensional material layers. The two-dimensional material layer 220 may be formed by chemical vapor deposition, such as metal organic chemical vapor deposition (MOCVD), plasma chemical vapor deposition (PECVD), or thermal chemical vapor deposition, but is not limited thereto.

Referring to FIG. 5D, the charge trap layer 223 may be formed on the two-dimensional material layer 220. When a three-dimensional charge trap layer 223 is formed on the two-dimensional material layer 220, the charge trap layer 223 develops island growth. Therefore, the charge trap layer 223 includes a plurality of grain boundaries. The plurality of grain boundaries may serve to limit and/or prevent lateral charge spreading inside the charge trap layer 223. In addition, the charge trap layer 223 may be provided on the two-dimensional material layer 220 to increase trap energy and trap density compared to the charge trap layer without the existing two-dimensional material layer 220.

Referring to FIG. 5E, the tunneling barrier layer 224, the channel layer 225, and the filling insulation layer 226 may be sequentially formed on the charge trap layer 223.

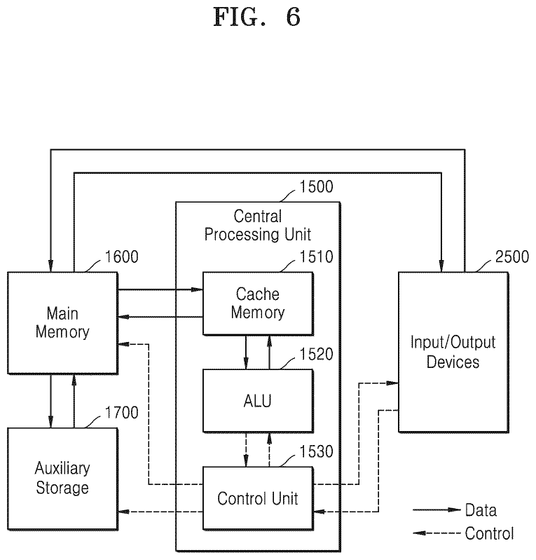

FIG. 6 is a conceptual diagram schematically showing a device architecture applicable to an electronic device according to embodiments.

Referring to FIG. 6, a cache memory 1510, an arithmetic unit (ALU) 1520, and a control unit 1530 may configure a central processing unit (CPU) 1500, and the cache memory 1510 may be configured as a static random access memory (SRAM). Apart from the CPU 1500, a main memory 1600 and an auxiliary storage 1700 may be provided. The main memory 1600 may include a DRAM device, and the auxiliary storage 1700 may include any one of the memory devices 100, 101, and 200 described above. In some cases, the device architecture may be implemented in a form in which computing unit elements and memory unit elements are adjacent to each other in one chip without division of sub-units. One or more input/output devices 2500 (e.g., keyboard, display, mouse, and the like) may be connected to the main memory 1600, auxiliary storage 1700, and/or and CPU 1500.

In example embodiments, a memory system may include an electronic device with a device architecture including the features in FIG. 6. The memory system may include a host (not shown) and the CPU 1500 may read data from the main memory 1600 and write data into the main memory 1600 in response to read and write requests from the host.

The memory device including the two-dimensional material layer according to the embodiments includes a charge trap layer on a two-dimensional material layer having low electron affinity, thereby improving trap density of the charge trap layer and reducing lateral charge diffusion of the charge trap layer. The memory device including the two-dimensional material layer has been described with reference to the embodiments shown in the drawings. According to the embodiments, the memory device may improve the trap density of the charge trap layer by providing the charge trap layer on the two-dimensional material layer.

According to the embodiments, the memory device may improve the lateral charge diffusion of the charge trap layer by providing the charge trap layer on the two-dimensional material layer.

According to the embodiments, the memory device may limit and/or prevent electrons moving from the channel layer to the charge trap layer from reaching the gate electrode by providing the charge trap layer on the two-dimensional material layer having low electron affinity.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A memory device comprising:
a gate electrode;
a channel layer spaced apart from the gate electrode;
a charge trap layer between the gate electrode and the channel layer; and
a two-dimensional material layer between the charge trap layer and the gate electrode, wherein
the two-dimensional material layer includes a material having an electron affinity of less than 1 eV.

2. The memory device of claim 1, wherein the two-dimensional material layer comprises at least one of CaF₂, NaF, MgF₂, CdF₂, MoS₂, MoSe₂, WS₂, and WSe₂.

3. The memory device of claim 1, wherein the two-dimensional material layer comprises an insulator material.

4. The memory device of claim 1, wherein the two-dimensional material layer comprises a material with a band gap of 10 eV or more.

5. The memory device of claim 1, wherein a sum of a thickness of the two-dimensional material layer and a thickness of the charge trap layer is 10 nm or less.

6. The memory device of claim 1, wherein the two-dimensional material layer comprises a first two-dimensional material layer and a second two-dimensional material layer.

7. The memory device of claim 6, wherein the first two-dimensional material layer and the second two-dimensional material layer comprise different materials.

8. The memory device of claim 1, wherein
the charge trap layer comprises a material having a trap density of 10¹⁸/cm³ or more and 10²⁰/cm³ or less.

9. The memory device of claim 1, wherein the charge trap layer comprises silicon nitride, SiO₂, HfO₂, or TiO₂.

10. The memory device of claim 1, wherein
the charge trap layer comprises a plurality of grain boundaries.

11. The memory device of claim 1, further comprising
a tunneling barrier layer between the charge trap layer and the channel layer.

12. The memory device of claim 1, further comprising
a blocking insulating layer between the two-dimensional material layer and the gate electrode.

13. A memory device comprising:
a substrate; and
a plurality of memory cell arrays on the substrate, wherein
each of the plurality of memory cell arrays comprises a channel layer extending in a first direction, a plurality of gate electrodes spaced apart from the channel layer in a second direction and alternately arranged in the first direction, a charge trap layer between the channel layer and the plurality of gate electrodes, and a two-dimensional material layer between the charge trap layer and the plurality of gate electrodes,
the second direction is different than the first direction, and
the two-dimensional material layer includes a material having electron affinity of less than 1 eV.

14. The memory device of claim 13, wherein the two-dimensional material layer comprises at least one of CaF₂, NaF, MgF₂, CdF₂, MoS₂, MoSe₂, WS₂, and WSe₂.

15. The memory device of claim 13, wherein the two-dimensional material layer comprises a material with a band gap of 10 eV or more.

16. The memory device of claim 13, wherein the memory cell array extends in a direction perpendicular to the substrate.

17. The memory device of claim 13, wherein the two-dimensional material layer comprises a first two-dimensional material layer and a second two-dimensional material layer.

18. The memory device of claim 13, wherein the charge trap layer comprises a material having a trap density of 10¹⁸/cm³ or more and 10²⁰/cm³ or less.

19. The memory device of claim 13, wherein the charge trap layer comprises silicon nitride, SiO₂, HfO₂, or TiO₂.

20. The memory device of claim 13, wherein the charge trap layer comprises a plurality of grain boundaries.
